(19) United States
(12) Patent Application Publication
(10) Pub. No.: US 2025/0079151 A1
(43) Pub. Date: Mar. 6, 2025

(54) SUBSTRATE PROCESSING METHOD AND SUBSTRATE PROCESSING SYSTEM

(71) Applicant: SCREEN Holdings Co., Ltd., Kyoto-shi (JP)

(72) Inventor: Noritake SUMI, Kyoto (JP)

(21) Appl. No.: 18/679,534

(22) Filed: May 31, 2024

(30) Foreign Application Priority Data
Aug. 28, 2023 (JP) 2023-138193

(51) Int. Cl. H01L 21/02; H01L 21/67

(52) U.S. Cl. CPC H01L 21/02101; H01L 21/67034

(57) ABSTRACT

In the substrate processing method according to the invention, a liquid film of an organic solvent is formed in a liquid-filled state (puddle state) after a liquid adhering to a pattern formed surface of the substrate is replaced by the organic solvent. At least one of a first vibration application processing to a third vibration application processing executes. The first vibration application processing is a process of applying vibration to the substrate after the liquid-filled state is created in a wet processing device. The second vibration application processing is a process of applying vibration to the substrate in a substrate conveying device. The third vibration application processing is a process of applying vibration to the substrate before a processing fluid in a supercritical state is brought into contact with the pattern formed surface in a supercritical processing device.

### CROSS REFERENCE TO RELATED APPLICATION

The disclosure of Japanese Patent Application No. 2023-138193 filed on Aug. 28, 2023 including specification, drawings and claims is incorporated herein by reference in its entirety.

### BACKGROUND OF THE INVENTION

### 1. Field of the Invention

This invention relates to a technique for drying a substrate in a processing chamber and particularly to a process for processing a substrate covered with a liquid film by a processing fluid in a supercritical state.

### 2. Description of the Related Art

Processing steps of various substrates such as semiconductor substrates and glass substrates for display device include processing of a substrate surface by various processing fluids. A wet processing using a liquid such as a chemical or a rinse liquid as a processing fluid has been conventionally widely performed. In recent years, a processing using a processing fluid in a supercritical state has also been put to practical use to dry the substrate after this wet processing. Particularly, this is useful in a dry processing of a substrate having a pattern formed surface formed with a fine pattern. This is because the processing fluid in the supercritical state has a property of having a lower surface tension than liquids and entering deep into gaps of the pattern. By using this processing fluid, the dry processing can be efficiently performed. Further, it is also possible to reduce an occurrence risk of pattern collapse due to a surface tension during drying.

For example, in a substrate processing system described in JP 2013-201302A, a substrate developing device is provided as an example of a “wet processing device” of the invention. In this substrate developing device, an IPA (isopropyl alcohol) liquid, which is an example of an “organic solvent” of the invention, is supplied to a substrate wetted with a rinse liquid as a final processing in this device. In this way, IPA replacement is performed and the rinse liquid is removed from the surface of the substrate. Further, a liquid-filled state is created by filling the IPA liquid on the surface of the substrate. That is, a liquid film containing the IPA liquid is formed into a puddle shape. As a result, the surface of the substrate is maintained in a state wetted with the IPA liquid. Then, the substrate maintained in the liquid-filled state is conveyed to a substrate drying device corresponding to an example of a “supercritical processing device” of the invention by a substrate conveying device, and a dry processing by a processing fluid in a supercritical state is performed.

### SUMMARY OF INVENTION

In a wet processing device such as a substrate developing device or a substrate cleaning device, a liquid such as a rinse liquid is desirably completely discharged from the inside of a pattern by IPA replacement. However, the liquid may remain on the inner bottom surface of the pattern. If the substrate is carried into a substrate drying device (supercritical processing device) while the liquid remaining in this way (hereinafter, referred to as a “remaining liquid”) is left unremoved and a supercritical dry processing is performed, the following problem may occur. That is, the replacement of a liquid component constituting a liquid film and a processing fluid in a supercritical state tends to be incomplete. Thus, a measure for increasing a use amount of the processing fluid is thought to cover that problem. However, this leads to an increase of running cost and gives a large environmental burden on the society.

Further, even if the use amount of the processing fluid was increased, the remaining liquid might have remained on the inner bottom surface of the pattern and caused pattern collapse. Thus, the presence of the remaining liquid is one of main factors for reducing a product yield.

This invention was developed in view of the above problem and aims to provide a technique capable of improving a yield while reducing an environmental burden by reducing the consumption of a processing fluid in a substrate processing system for conveying a substrate in a state filled with an organic solvent on a surface of the substrate subjected to a wet processing from a wet processing device to a supercritical processing device and drying the substrate using a processing fluid in a supercritical state.

One aspect of this invention is directed to a substrate processing method for drying a substrate having a pattern formed surface formed with a pattern and a liquid adhering to the pattern formed surface. The method comprises: (a) creating a liquid-filled state in which an organic solvent is filled on the pattern formed, the organic solvent being supplied to the pattern formed surface to replace the liquid in a wet processing device; (b) conveying the substrate in the liquid-filled state from the wet processing device to a supercritical processing device; (c) drying the substrate by bringing a processing fluid in a supercritical state into contact with the pattern formed surface in the liquid-filled state in the supercritical processing device; and (d) mixing the liquid remaining in the pattern with the organic solvent by applying vibration to the substrate while maintaining the liquid-filled state before the processing fluid in the supercritical state is brought into contact with the pattern formed surface.

Other aspect of the invention is a substrate processing system for drying a substrate having a pattern formed surface formed with a pattern and a liquid adhering to the pattern formed surface. The system comprises: a wet processing device configured to create a liquid-filled state in which an organic solvent is filled on the pattern formed, the organic solvent being supplied to the pattern formed surface to replace the liquid; a supercritical processing device configured to dry the substrate by bringing a processing fluid in a supercritical state into contact with the pattern formed surface in the liquid-filled state; a substrate conveying device configured to convey the substrate in the liquid-filled state from the wet processing device to the supercritical processing device; and a control device configured to control the wet processing device, the substrate conveying device and the supercritical processing device to perform at least one of a first vibration application processing to a third vibration application processing, the first vibration application processing being a process of applying vibration to the substrate after the liquid-filled state is created in the wet processing device, a second vibration application processing being a process of applying vibration to the substrate in the substrate conveying device, the third vibration application processing being a process of applying vibration to the substrate before the processing fluid in the supercritical state is brought into contact with the pattern formed surface in the supercritical processing device.

In the invention thus configured, a liquid film of the organic solvent is formed in the liquid-filled state (puddle state) after the liquid adhering to the pattern formed surface of the substrate is replaced by the organic solvent. Here, if the liquid remains on the inner bottom surface of the pattern, this remaining liquid causes an increase in the consumption of the processing fluid and a yield reduction. Accordingly, in the invention, vibration is applied to the substrate in the liquid-filled state before the processing fluid in the supercritical state is brought into contact with the pattern formed surface of the substrate. In this way, the liquid remaining in the pattern is transferred and diffused, and mixed with the organic solvent. As a result, a dry processing by the processing fluid in the supercritical state is performed in the absence of the remaining liquid on the inner bottom surface of the pattern, i.e. in a so-called remaining liquid-free state.

As described above, according to the invention, a supercritical dry processing can be performed in a remaining liquid-free state. As a result, a yield can be improved while the consumption of a processing fluid is reduced.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF THE DRAWINGS

FIG. 1 is a drawing showing a schematic configuration of a first embodiment of a substrate processing system according to the present invention.

FIG. 2A is a side view showing the overall configuration of the wet processing device.

FIG. 2B is a diagram showing the operation of the wet processing device.

FIG. 3 is diagrams schematically showing the configuration and operation of the chuck pin.

FIG. 4 is a side view showing the configuration of the supercritical processing device.

FIG. 5 is a perspective view showing the structure of the support tray.

FIG. 6 is a flow chart outlining the processing performed by the substrate processing system according to the first embodiment.

FIG. 7 is a chart showing a pressure change in the processing chamber.

FIG. 8 is a flow chart outlining a processing performed by a substrate processing system according to the fifth embodiment.

FIG. 9 is a flow chart outlining a processing performed by a substrate processing system according to the sixth embodiment.

### DETAILED DESCRIPTION OF THE PREFERRED EMBODIMENTS

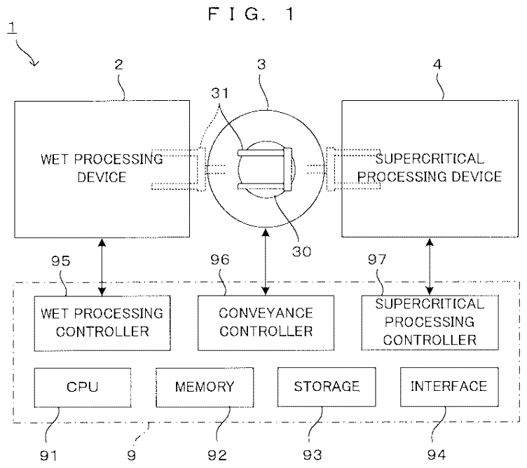

FIG. 1 is a drawing showing a schematic configuration of a first embodiment of a substrate processing system according to the present invention. This substrate processing system 1 is a processing system for wet-processing various substrates such as semiconductor wafers by supplying a processing fluid to the upper surfaces of the substrates and, thereafter, drying the substrates. The substrate processing system 1 has a suitable system configuration to carry out a substrate processing method according to the invention. That is, the substrate processing system 1 is provided with a wet processing device 2, a substrate conveying device 3 and a control device 9.

The wet processing device 2 performs a predetermined wet processing by receiving a substrate to be processed. Contents of the processing are not particularly limited. The wet processing includes a development processing and a cleaning processing of cleaning the substrate by a chemical, which processings are performed by the above conventional device, and a liquid-filled state filled with an organic solvent such as an IPA liquid is created on a pattern formed surface of the substrate. The substrate conveying device 3 carries out and conveys the substrate from the substrate processing device 2 with the liquid-filled state maintained, and carries the substrate into the supercritical processing device 4. The supercritical processing device 4 performs a dry processing (supercritical dry processing) using a processing fluid in a supercritical state for the carried-in substrate. These are installed in a clean room. Therefore, the substrate conveying device 3 conveys the substrate S in an air atmosphere and under an atmospheric pressure.

The control device 9 realizes a predetermined process by controlling these components of the device. For this purpose, the control device 9 includes a CPU 91, a memory 92, a storage 93, an interface 94, and the like. The CPU 91 executes various control programs. The memory 92 temporarily stores processing data. The storage 93 stores the control programs to be executed by the CPU 91. The interface 94 performs information exchange with a user and an external device. Operations of the device to be described later are realized by the CPU 91 causing each component of the device to perform a predetermined operation by executing the control program written in the storage 93 in advance.

The CPU 91 executes a predetermined control program, whereby functional blocks such as a wet processing controller 95 for controlling the operation of the wet processing device 2, a conveyance controller 96 for controlling the operation of the substrate conveying device 3 and a supercritical processing controller 97 for controlling the operation of the supercritical processing device 4 are realized by software in the control device 9. Note that each of these functional blocks may be at least partially configured by dedicated hardware.

Here, various substrates such as semiconductor wafers, glass substrates for photomask, glass substrates for liquid crystal display, glass substrates for plasma display, substrates for FED (Field Emission Display), optical disk substrates, magnetic disk substrates and magneto-optical disk substrates can be applied as the “substrate” in this embodiment. The substrate processing device used in processing semiconductor wafers is mainly described as an example with reference to the drawings below. However, application to the processing of various substrates illustrated above is also possible. Further, various shape of the substrate are also available.

A substrate S used as an example in the following description has a circuit pattern, etc. formed only on one main surface thereof. Here, a surface corresponding to the main surface with the circuit pattern, etc. will be called a “front surface,” and a main surface on the opposite side without a circuit pattern, etc. will be called a “back surface.” Furthermore, a surface of the substrate S facing downward will be called a “lower surface,” and a surface of the substrate S facing upward will be called an “upper surface.” In the example descried below, the front surface corresponds to the upper surface.

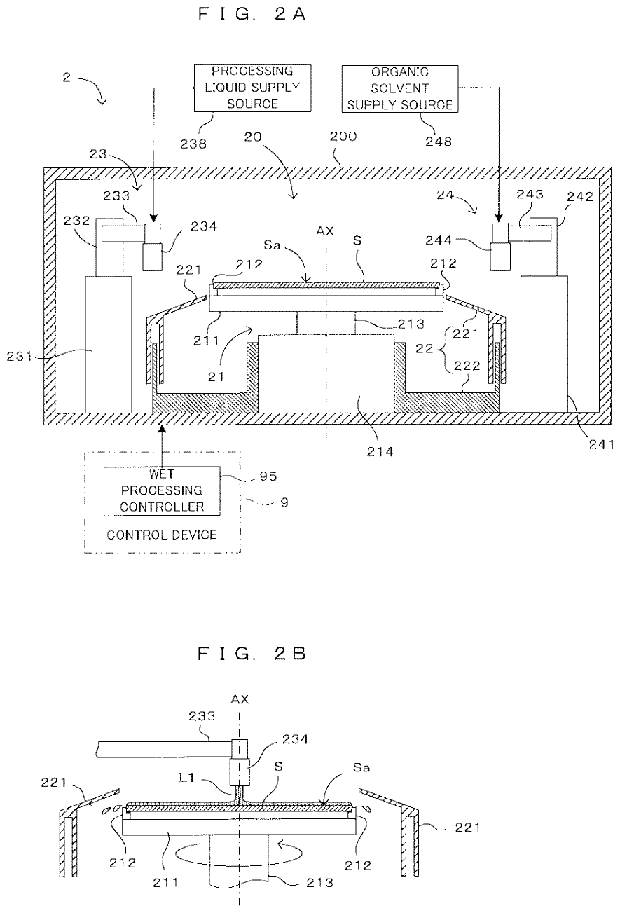

FIGS. 2A and 2B are diagrams showing a configuration example of the wet processing device. More specifically, FIG. 2A is a side view showing the overall configuration of the wet processing device, and FIG. 2B is a diagram showing the operation of the wet processing device. This wet processing device 2 is a device for processing the substrate by supplying the processing fluid to the upper surface of the substrate S. The operation of the wet processing device 2 is controlled by the wet processing controller 95 of the control device 9.

The wet processing device 2 performs a surface processing of the substrate S and a wet processing such as washing by supplying the processing liquid to the upper surface (pattern formed surface) Sa of the substrate S. For this purpose, the wet processing device 2 is provided with a substrate holder 21, a splash guard 22 and processing liquid suppliers 23, 24 inside the processing chamber 200. The operations of these are controlled by the wet processing controller 95 provided in the control device 9. The substrate holder 21 includes a disk-like spin chuck 211 having a diameter nearly equal to that of the substrate S, and a plurality of chuck pins 212 are provided on a peripheral edge part of the substrate S.

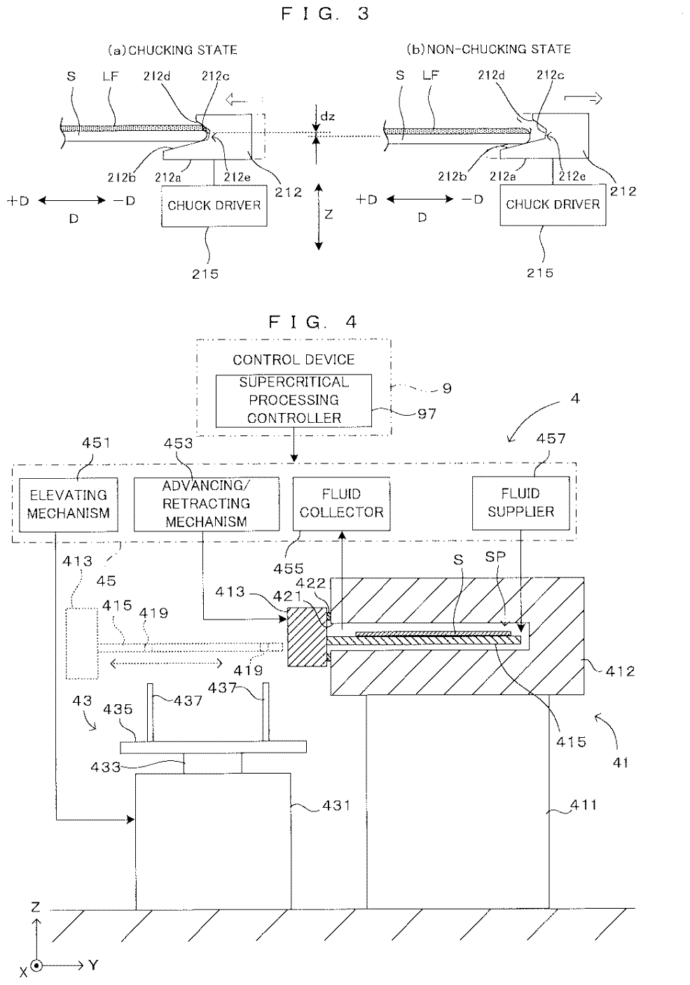

FIG. 3 is diagrams schematically showing the configuration and operation of the chuck pin, wherein FIG. 3(a) shows the chuck pin in a chucking state (sandwiching state) and FIG. 3(b) shows the chuck pin in a non-chucking state (releasing state). Although not shown, twelve chuck pins 212 are radially provided about an axis of rotation AX of the chuck pins 212 as a center in this embodiment. Each chuck pin 212 is arranged movably in a radial direction D on the upper surface of a peripheral edge part of the spin chuck 211. The “radial direction D” mentioned here means a longitudinal direction of a virtual line connecting the axis of rotation AX and the chuck pin 212.

Any of the plurality of chuck pins 212 has the same configuration. Accordingly, the configuration of one chuck pin 212 is described below and each part of the other chuck pins 212 is denoted by the same reference sign and not described. As shown in FIG. 3, the chuck pin 212 has a chuck contact surface 212a. This chuck contact surface 212a is movable along the radial direction D on the upper surface of the peripheral edge part of the spin chuck 211. In the chuck pin 212, a lower contact surface 212b is provided above the chuck contact surface 212a. The lower contact surface 212b is inclined downward in a (+D) direction toward the axis of rotation AX. A curved contact surface 212c is provided to extend upward from an end part of this lower contact surface 212b on a (−D) direction side. This curved contact surface 212c is finished into a curved surface facing toward the axis of rotation AX. Further, an upper contact surface 212d is provided to extend upward from an upper end of the curved contact surface 212c. This upper contact surface 212d is inclined upward in the (+D) direction toward the axis of rotation AX. More particularly, as shown in FIG. 3, the curved contact surface 212c is directly connected to the upper and lower contact surfaces 212d, 212b while being arranged between the upper and lower contact surfaces 212d, 212b. Therefore, if a substrate contact part 212e, in which the upper contact surface 212d, the curved contact surface 212c and the lower contact surface 212b are connected and in contact with the substrate S, is viewed from a horizontal direction orthogonal to the radial direction D, the substrate contact part 212e is substantially C-shaped. That is, the chuck pin 212 is reciprocally movable along the radial direction D with the substrate contact part 212e facing the axis of rotation AX.

The chuck pin 212 is connected to a chuck driver 215. The chuck driver 215 moves the chuck pin 212 in the radial direction D in response to a command from the wet processing controller 95. For example, when the substrate S is transferred to the substrate conveying device 3, the chuck driver 215 moves the chuck pin 212 in the (−D) direction and positions the chuck pin 212 at the non-chucking position (corresponding to an example of a “releasing position” of the invention) as shown in FIG. 3(b). At this time, the curved contact surface 212c and the upper contact surface 212d are separated from the axis of rotation AX by a distance slightly longer than a radius of the substrate S. On the other hand, the lower contact surface 212b is located below the substrate S. Therefore, as shown in FIG. 3(b), the substrate S is supported at a position of the lower contact surface 212b separated toward the (+D) direction side from the curved contact surface 212c only by the lower contact surface 212b.

On the other hand, in chucking the substrate S, the chuck driver 215 moves the chuck pin 212 in the (+D) direction and positions the chuck pin 212 at the chucking position (corresponding to an example of a “sandwiching position” of the invention) as shown in FIG. 3(a). By moving the chuck pin 212 from the non-chucking position to the chucking position in this way, the support position of the substrate S by the lower contact surface 212b is shifted in the (−D) direction. When the movement of this chuck pin 212 to the chucking position is completed, the substrate S is supported by the lower contact surface 212b, the curved contact surface 212c and the upper contact surface 212d. That is, substrate chucking is completed.

In releasing the chucking of the substrate S, the chuck pin 212 is moved in a procedure reverse from the above procedure and the support position of the substrate S by the lower contact surface 212b is shifted in the (+D) direction.

Further, by moving the support position of the substrate S by the lower contact surface 212b in the radial direction D, the height position of the substrate S in a vertical direction Z is displaced by a distance dz. Accordingly, if the wet processing controller 95 gives a reciprocal movement command to the chuck driver 215, the chuck pin 212 is reciprocated in the radial direction D and lifting and lowering movements of the substrate S are synchronously repeated. That is, vibration in the vertical direction can be applied to the substrate S. In this embodiment, the aim of the invention is achieved utilizing this vibration application. This point is described in detail later together with the description of the operation of the substrate processing system 1.

Returning to FIGS. 2A and 2B, we continue with the explanation of the configuration of the wet processing device 2. The spin chuck 211 is so supported that the upper surface thereof is horizontal by a rotary support shaft 213 extending downward from a central part of the lower surface of the spin chuck 211. The rotary support shaft 213 is rotatably supported by a rotating mechanism 214 mounted in a bottom part of the processing chamber 200. The rotating mechanism 214 includes an unillustrated built-in rotary motor. The rotary motor rotates in response to a control command from the control device 9, whereby the spin chuck 211 directly coupled to the rotary support shaft 213 rotates about the axis of rotation AX indicated by a dashed-dotted line. In FIGS. 2A and 2B, an up-down direction is a vertical direction. In this way, the substrate S is rotated about the axis of rotation AX while being held in the horizontal posture.

The splash guard 22 is provided to laterally surround the substrate holder 21. The splash guard 22 includes a substantially tubular cup 221 provided to cover the peripheral edge part of the spin chuck 211 and a liquid receiver 222 provided below an outer peripheral part of the cup 221. The cup 211 is raised and lowered in response to a control command from the control device 9. The cup 221 is raised and lowered between a lower position where an upper end part of the cup 221 is lowered to below the peripheral edge part of the substrate S held by the spin chuck 211 as shown by solid lines in FIG. 3 and an upper position where the upper end part of the cup 221 is located above the peripheral edge part of the substrate S as shown by dotted lines in FIG. 3.

As shown by solid lines in FIG. 2A, when the cup 221 is at the lower position, the substrate S held by the spin chuck 211 is exposed to the outside of the cup 221. Thus, the cup 221 is, for example, prevented from becoming an obstacle when the substrate S is carried to and from the spin chuck 211.

Further, as indicated by dotted lines in FIG. 2B, the cup 221 surrounds the peripheral edge part of the substrate S held by the spin chuck 211 when being at the upper position. In this way, the processing liquid shaken off from the peripheral edge part of the substrate S during liquid supply to be described later is prevented from scattering in the chamber 200, and the processing liquid can be reliably collected. That is, by the rotation of the substrate S, droplets of the processing liquid shaken off from the peripheral edge part of the substrate S adhere to the inner wall of the cup 221, flow down and are finally gathered and collected by the liquid receiver 222 arranged below the cup 221. To individually collect a plurality of processing liquids, cups may be concentrically provided at a plurality of levels.

The processing liquid supplier 23 is structured such that a nozzle 234 is attached to the tip of an arm 233 horizontally extending from a rotary support shaft 232 provided rotatably with respect to a base 231 fixed in the processing chamber 200. The rotary support shaft 232 rotates in response to a control command from the control device 9, whereby the arm pivots and the nozzle 234 on the tip of the arm 233 moves between a retreated position (FIG. 2A) retracted laterally from above the substrate S and a processing position (FIG. 2B) above the substrate S.

The nozzle 234 is connected to a processing liquid supply source 238. If an appropriate processing liquid is sent out from the processing liquid supply source 238, the processing liquid is discharged toward the substrate S from the nozzle 234. By supplying the processing liquid L1 from the nozzle 234 positioned above a center of rotation of the substrate S while rotating the substrate S by the rotation of the spin chuck 211 at a relatively low speed, an upper surface Sa of the substrate S is processed by the processing liquid L1. Liquids having various functions such as developers, etching liquids, cleaning liquids and rinsing liquids can be used as the processing liquid, and a composition of the processing liquid is arbitrary. Further, the processing may be performed with a plurality of types of processing liquids combined.

Another processing liquid supplier 24 also has a configuration corresponding to the first processing liquid supplier 23 described above. That is, processing liquid supplier 24 includes a base 241, a rotary support shaft 242, an arm 243, a nozzle 244 and the like, and the configurations of these are the same as those of the corresponding components of the first processing liquid supplier 23. The rotary support shaft 242 rotates in response to a control command from the control device 9, whereby the arm 243 pivots. The nozzle 244 on the tip of the arm 243 supplies a processing liquid to the upper surface Sa of the substrate S.

In this wet processing device 2, the second processing liquid supplier 24 is used for the purpose of forming a liquid film for dry prevention on the substrate S after the wet processing. That is, the substrate S after the wet processing is conveyed to the supercritical processing device 4 and receives a supercritical drying processing. To prevent the surface of the substrate S from being exposed and oxidized during conveyance and prevent the collapse of the fine pattern formed on the surface, the substrate S is conveyed with the surface thereof covered with a puddle-like liquid film.

A substance having a lower surface tension than water, which is a main component of a processing liquid used in a cleaning processing, e.g. an organic solvent such as isopropyl alcohol (IPA) or acetone, is used as the liquid for constituting the liquid film. These organic solvents are supplied from an organic solvent supply source 248.

Although two processing liquid suppliers are provided in the wet processing device 2 here, the number, structures and functions of the processing liquid suppliers are not limited to these. For example, only one processing liquid supplier may be provided or three or more processing liquid suppliers may be provided. Further, one processing liquid supplier may include a plurality of nozzles. For example, a plurality of nozzles may be provided on the tip of one arm. Further, the processing liquid is not only discharged with the nozzle positioned at the predetermined position as described above, but also may be, for example, discharged while the nozzle is scanned and moved along the upper surface Sa of the substrate S.

Referring back to FIG. 1, description is continued. The substrate conveying device 3 is provided with a conveyor robot 30 provided with a hand 31 on the tip of a telescopic/rotatable arm. The hand 31 can support the substrate by partially contacting the lower surface of the substrate and, as shown by dotted lines in FIG. 1, is movable toward and away from both the wet processing device 2 and the supercritical processing device 4. In this way, the substrate can be carried in and out from each of the wet processing device 2 and the supercritical processing device 4. The operation of the conveyor robot 30 is controlled by the conveyance controller 96 of the control device 9. Many techniques are known as conveyor robots of this type. Since one of those can be appropriately selected and used also in this embodiment, detailed description is omitted.

FIG. 4 is a side view showing the configuration of the supercritical processing device. The supercritical processing device 4 is a device for applying a drying processing using a processing fluid in a supercritical state to the substrate S after the wet processing. More specifically, the supercritical processing device 4 is a device for finally bringing the substrate S to a dry state by discharging the processing fluid after receiving the substrate S after the wet processing and replacing the liquid remaining on the substrate S by the processing fluid in the supercritical state.

The supercritical processing device 4 is provided with a processing unit 41 and a transfer unit 43 provided in the processing chamber 400 and a supply unit 45. The processing unit 41 serves as an executor of the supercritical drying processing. The transfer unit 43 receives the substrate S after the wet processing conveyed by the substrate conveying device 3, carries the substrate S into the processing unit 41 and transfers the processed substrate S from the processing unit 41 to the conveyor device 3. The supply unit 45 supplies chemical substances, power, energy and the like necessary for the processing to the processing unit 41 and the transfer unit 43. These operations are controlled by the control device 9, particularly by the supercritical processing controller 97.

The processing unit 41 is structured such that a processing chamber 412 is mounted on a pedestal 411. The processing chamber 412 is configured by a combination of several metal blocks and the inside thereof is hollow and constitutes a processing space SP. The substrate S to be processed is carried into the processing space SP and processed. A slit-like opening 421 elongated in the X direction is formed in a side surface on the (−Y) side of the processing chamber 412. The processing space SP and an outside space communicate via the opening 421. A cross-sectional shape of the processing space SP is substantially the same as an opening shape of the opening 421. That is, the processing space SP is a hollow having a cross-sectional shape long in the X direction and short in the Z direction and extending in the Y direction.

A lid member 413 is provided to close the opening 421 on a side surface on the (−Y) side of the processing chamber 412. The lid member 413 closes the opening 421 of the processing chamber 412, whereby an airtight processing container is configured. In this way, the substrate S can be processed under a high pressure in the processing space SP inside. A support tray 415 in the form of a flat plate is mounted in a horizontal posture on a side surface on the (+Y) side of the lid member 413. The upper surface of the support tray 415 serves as a support surface, on which the substrate S can be placed. The lid member 413 is supported horizontally movably in the Y direction by an unillustrated supporting mechanism.

The lid member 413 is movable toward and away from the processing chamber 412 by an advancing/retracting mechanism 453 provided in the supply unit 45. Specifically, the advancing/retracting mechanism 453 includes a linear motion mechanism such as a linear motor, a linear motion guide, a ball screw mechanism, a solenoid or an air cylinder. Such a linear motion mechanism moves the lid member 413 in the Y direction. The advancing/retracting mechanism 453 operates in response to a control command from the control device 9.

If the lid member 413 is separated from the processing chamber 412 by moving in the (−Y) direction and the support tray 415 is pulled out from the processing space SP to outside via the opening 421 as indicated by a dotted line, the support tray 415 becomes accessible. That is, the substrate S can be placed on the support tray 415 and the substrate S placed on the support tray 415 can be taken out. On the other hand, by a movement of the lid member 413 in the (+Y) direction, the support tray 415 is accommodated into the processing space SP. If the substrate S is placed on the support tray 415, the substrate S is carried into the processing space SP together with the support tray 415.

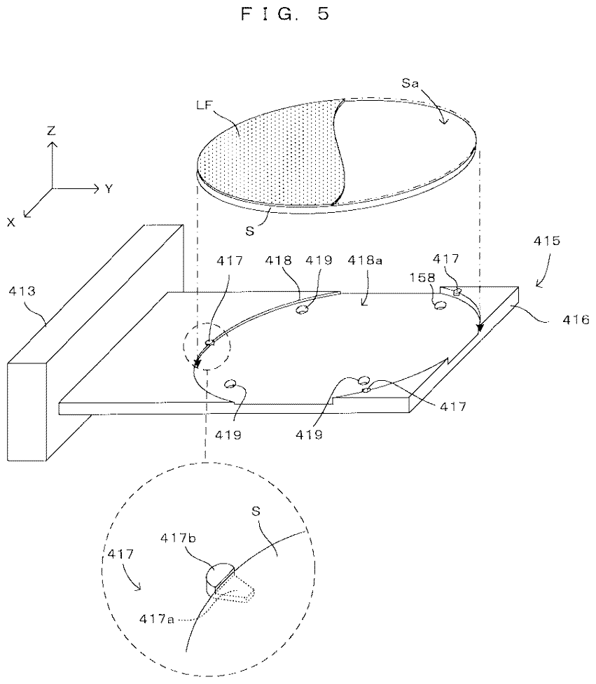

FIG. 5 is a perspective view showing the structure of the support tray. The support tray 415 includes a tray member 416 and a plurality of support pins 417. The tray member 415 is structured such that a recess 418 corresponding to the planar size of the substrate S, more specifically, having a diameter slightly larger than that of the circular substrate S, is provided in the horizontal and flat upper surface of a flat plate-like structure.

The recess 418 partially extends to the side surface of the tray member 416. That is, the side wall surface of the recess 48 is not circular, but partially cut. Thus, parts of a bottom surface 418a of the recess 418 are directly connected to the side surface in these cut parts. In this example, such cut parts are provided on both X side end parts and a (+Y) side end part of the support tray 415, and the bottom surface 418a is directly connected to the side surface in these parts.

Further, through holes 419, through which lift pins 437 are inserted, are perforated at positions of the bottom surface 418a corresponding to the lift pins 437 of the transfer unit 43. By lifting and lowering the lift pins 437 through the through holes 419, a state where the substrate S is accommodated in the recess 418 and a state where the substrate S is lifted up from the recess 418 are realized.

The plurality of support pins 417 are provided on a peripheral edge part of the recess 418. The number of the support pins 417 is arbitrary, but three or more support pins 417 are desirable to stably support the substrate S. In this embodiment, three support pins 417 are mounted on the tray member 416 to surround the bottom surface 418a in a plan view from above. As shown in a partial enlarged view in FIG. 5, the support pin 417 includes a height restricting part 417a and a horizontal position restricting part 417b.

The height restricting part 417a has a flat upper surface, and supports the substrate S and restricts the position of the substrate S in the vertical direction Z (hereinafter, referred to as a “height position”) by contacting a peripheral edge part of the lower surface of the substrate S. On the other hand, the horizontal position restricting part 417b extends further upward than the upper end of the height restricting part 417a and restricts the position of the substrate S in a horizontal direction (XY direction) by contacting the side surface of the substrate S. By such support pins 417, the substrate S are supported in a horizontal posture separated upward from the bottom surface 418a of the recess 418 while facing the bottom surface 418a.

The processing space SP is closed by the lid member 413 moving in the (+Y) direction and closing the opening 421. A sealing member 422 is provided between the side surface on the (+Y) side of the lid member 413 and the side surface on the (−Y) side of the processing chamber 412 to hold the processing space SP airtight. The sealing member 422 is, for example, made of rubber. Further, the lid member 413 is fixed to the processing chamber 412 by an unillustrated lock mechanism. As just described, in this embodiment, the lid member 413 is switched between a closing state (solid line) for sealing the processing space SP by closing the opening 421 and a separated state (dotted line) where the lid member 413 is largely separated from the opening 421 to enable the substrate S to be taken in and out.

With the airtight state of the processing space SP ensured, the substrate S is processed in the processing space SP. In this embodiment, a fluid supplier 457 provided in the supply unit 45 sends out a processing fluid of a substance usable in the supercritical processing, e.g. carbon dioxide, as the processing fluid and further brings the processing fluid into a supercritical state by pressurizing the processing fluid in the processing chamber 412. The processing fluid is supplied in a gas or liquid state to the processing unit 41. Carbon dioxide is a chemical substance suitable for the supercritical drying processing in having a property of entering the supercritical state at relatively low temperature and low pressure and dissolving into an organic solvent often used in substrate processing well. At a critical point at which carbon dioxide enters the supercritical state, an atmospheric pressure (critical pressure) is 7.38 MPa and a temperature (critical temperature) is 31.1° C.

If the processing fluid is filled into the processing space SP and the inside of the processing space SP reaches suitable temperature and pressure, the processing space SP is filled with the processing fluid in the supercritical state. In this way, the substrate S is processed by the processing fluid in the supercritical state in the processing chamber 412. The supply unit 45 is provided with a fluid collector 455, and the fluid after the processing is collected by the fluid collector 455. The fluid supplier 457 and the fluid collector 455 are controlled by the supercritical processing controller 97.

The processing space SP has a shape and a volume capable of receiving the support tray 415 and the substrate S supported by the support tray 415. That is, the processing space SP has a substantially rectangular cross-sectional shape wider than a width of the support tray 415 in a horizontal direction and having a height larger than that of the support tray 415 and substrate S combined in the vertical direction, and has a depth capable of receiving the support tray 415. As just described, the processing space SP has a shape and a volume enough to receive the support tray 415 and the substrate S. Gaps between the support tray 415 and the substrate S and the inner wall surface of the processing space SP are tiny. Therefore, the amount of the processing fluid necessary to fill the processing space SP can be relatively small.

The fluid supplier 457 supplies the processing fluid to the processing space SP on a side further in the (+Y) direction than the end part on the (+Y) side of the substrate S. On the other hand, the fluid collector 455 discharges the processing fluid flowing in a space above the substrate S and a space below the support tray 415, out of the processing space SP, on a side further in the (−Y) direction than the end part on the (−Y) side of the substrate S. In this way, laminar flows of the processing fluid from the (+Y) side toward the (−Y) side are respectively formed above the substrate S and below the support tray 415 in the processing space SP.

The supercritical processing controller 97 of the control device 9 specifies the pressure and temperature in the processing space SP based on a detection result of an unillustrated detector and controls the fluid supplier 457 and the fluid collector 455 based on that result. In this way, the supply of the processing fluid into the processing space SP and the discharge of the processing fluid from the processing space SP are properly managed and the pressure and temperature in the processing space SP are adjusted according to a processing recipe determined in advance.

The transfer unit 43 is in charge of the transfer of the substrate S between the substrate conveying device 3 and the support tray 415. For this purpose, the transfer unit 43 is provided with a body 431, an elevating member 433, a base member 435 and a plurality of lift pins 437. The elevating member 433 is a columnar member extending in the Z direction, and supported movably in the Z direction with respect to the body 431 by an unillustrated supporting mechanism. The base member 435 having a substantially horizontal upper surface is mounted atop the elevating member 433. The plurality of lift pins 437 stand up from the upper surface of the base member 435. The respective lift pins 437 support the substrate S in a horizontal posture from below by the contact of upper end parts thereof with the lower surface of the substrate S. Three or more lift pins 437 having the upper end parts at the same height are desirably provided to stably support the substrate S in the horizontal posture.

The elevating member 433 is made movable up and down by an elevating mechanism 451 provided in the supply unit 45. Specifically, the elevating mechanism 451 includes a linear motion mechanism such as a linear motor, a linear motion guide, a ball screw mechanism, a solenoid or an air cylinder, and such a linear motion mechanism moves the elevating member 433 in the Z direction. The elevating mechanism 451 operates in response to a control command from the control device 9.

The base member 435 is moved up and down by upward and downward movements of the elevating member 433, and the plurality of lift pins 437 move up and down integrally with the base member 435. In this way, the transfer of the substrate S is realized between the transfer unit 43 and the support tray 415. More specifically, as shown by dotted lines in FIG. 4, the substrate S is transferred with the support tray 415 pulled out to the outside of the chamber. For this purpose, the support tray 415 is provided with through holes 419, through which the lift pins 437 are inserted. If the base member 435 is raised, the upper ends of the lift pins 437 reach above the upper surface of the support tray 415 through the through holes 419. In this state, the substrate S conveyed by the conveyor robot 30 is transferred from the hand 31 of the conveyor robot 30 to the lift pins 437. By lowering the lift pins 437, the substrate S is transferred from the lift pins 437 to the support tray 415. The substrate S can be carried out by a procedure opposite to the above one.

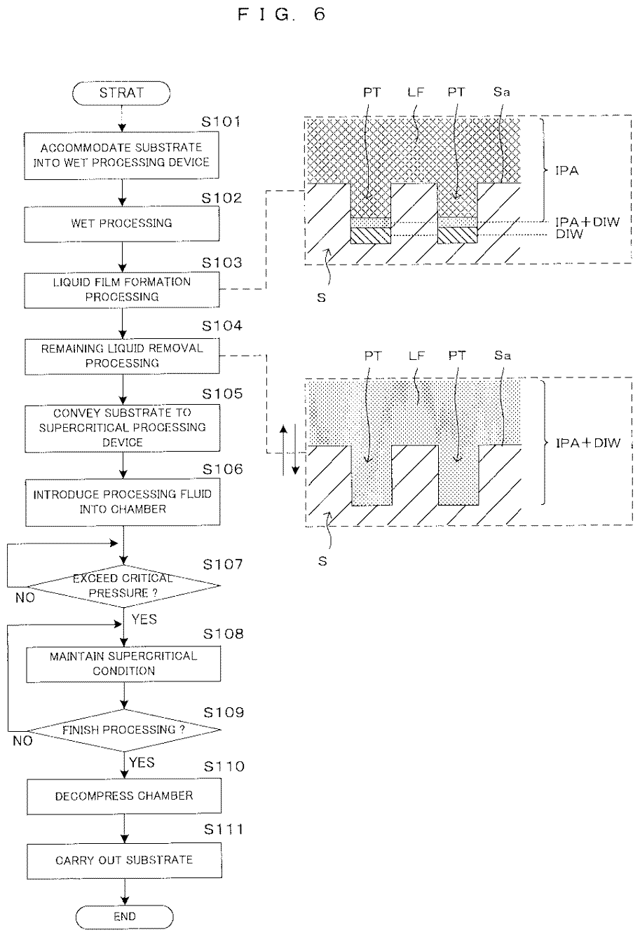

FIG. 6 is a flow chart outlining the processing performed by the substrate processing system according to the first embodiment. This substrate processing system 1 receives a substrate S to be processed and successively performs the wet processing using a processing fluid and the supercritical dry processing using a supercritical processing fluid. Specifically, the following Steps S101 to S111 are performed. The substrate S to be processed is accommodated into the wet processing device 2 constituting the substrate processing system 1 (Step S101). The substrate S may be directly carried in by an external conveying device or may be carried in from the external conveyor device via the conveyor robot 30.

The wet processing device 2 applies the wet processing to the substrate S using a predetermined processing fluid (Step S102). In this wet processing, a rinse liquid such as DIW (de-ionized water) is supplied to a surface Sa of the substrate S after a predetermined processing is performed by supplying a developer and a cleaning liquid. Accordingly, immediately after the wet processing is completed, the rinse liquid serving as an example of a “liquid” of the invention is adhering to the surface Sa of the substrate S. Thus, by supplying the organic solvent such as IPA to the substrate S after the wet processing, the rinse liquid adhering to the surface Sa of the substrate S is replaced by the organic solvent and a liquid-filled state filled with the organic solvent is created. That is, a liquid film LF is formed on the surface Sa of the substrate S (Step S103: liquid film formation processing).

The technical significance of the liquid film formation processing is as follows. For example, if the DIW is present in a pattern PT formed in the surface Sa of the substrate S, there is a possibility that the pattern PT collapses due to a surface tension of the DIW. Further, water marks may remain on the surface Sa of the substrate S due to incomplete drying. Furthermore, the surface Sa of the substrate S may undergo deterioration such as oxidation by being exposed to outside air. To avoid such a problem, the surface Sa of the substrate S is covered with the organic solvent. A liquid having a lower surface tension than the DIW and low in corrosivity to the substrate S, e.g. a liquid compatible with the DIW such as IPA and acetone, is suitably used as the organic solvent. A case where the DIW is used as the rinse liquid and the IPA is used as the organic solvent is described below.

Here, if replacement into the IPA is satisfactorily performed, the liquid film LF is made of only the IPA or a mixture of the IPA and the DIW. In this case, the DIW does not remain on the inner bottom surface of the pattern PT. However, in reality, the remaining liquid (DIW) may remain on the inner bottom surface of the pattern PT as shown in a right upper view in FIG. 6.

Accordingly, in this embodiment, the wet processing controller 95 gives a reciprocal movement command to the chuck driver 215 after the liquid-filled state is created in the wet processing device 2. Then, the chucking state shown in FIG. 3(a) and the non-chucking state shown in FIG. 3(b) are alternately repeated. That is, lifting and lowering movements of the substrate S are repeated as the chuck pins 212 are reciprocated in the radial direction D. In this way, vibration in the vertical direction Z is applied to the substrate S as shown in a lower figure of FIG. 6 and the remaining liquid is transferred and diffused into the IPA (Step S104). Even if the DIW remains on the inner bottom surface of the pattern PT when Step S103 is completed in this way, the remaining liquid is removed (remaining liquid removal processing).

After the remaining liquid removal processing, the liquid film LF free from the remaining liquid is formed on the surface Sa of the substrate S and the substrate S is conveyed from the wet processing device 2 to the supercritical processing device 4 by the substrate conveying device 3 while being kept in the liquid-filled state (Step S105).

The substrate S conveyed to the supercritical processing device 4 is accommodated into the processing chamber 412 while being kept in the liquid-filled state. Specifically, the substrate S is conveyed with the pattern formed surface (surface Sa) faced up and covered with the thin liquid film LF. As shown by dotted lines in FIG. 4, the lift pins 437 are lifted with the lid member 413 moved to the (−Y) side and the support tray 415 pulled out. The conveying device transfers the substrate S to the lift pins 437. By lowering the lift pins 437, the substrate S is placed on the support tray 415. If the support tray 415 and the lid member 413 integrally move in the (+Y) direction, the support tray 415 supporting the substrate S is accommodated into the processing space SP in the processing chamber 412 and the opening 421 is closed by the lid member 413.

In this state, carbon dioxide serving as the processing fluid is introduced in a gas phase state into the processing space SP (Step S106). Outside air enters the processing space SP when the substrate S is carried in. By introducing the processing fluid in a gas phase, the outside air can be replaced. By injecting the processing fluid in the gas phase, a pressure in the processing chamber 412 is increased.

Note that the processing fluid is continuously discharged from the processing space SP in the process of introducing the processing fluid. That is, the processing fluid is discharged from the processing space SP by the fluid collector 455 also while the processing fluid is introduced by the fluid supplier 457. In this way, the processing fluid used for the processing is discharged into the processing space SP without staying, and impurities such as residues taken into the processing fluid are prevented from re-adhering to the substrate S.

If a supply amount of the processing fluid is more than a discharge amount, a density of the processing fluid in the processing space SP increases and a chamber inner pressure increases. Conversely, if the supply amount of the processing fluid is less than the discharge amount, the density of the processing fluid in the processing space SP decreases and the chamber inner pressure decreases. The processing fluid is supplied into and discharged from the processing chamber 412 based on a supply/discharge recipe prepared in advance. That is, the control device 9 adjusts supply/discharge timings, a flow rate and the like of the processing fluid by controlling the fluid supplier 457 and the fluid collector 455 based on the supply/discharge recipe.

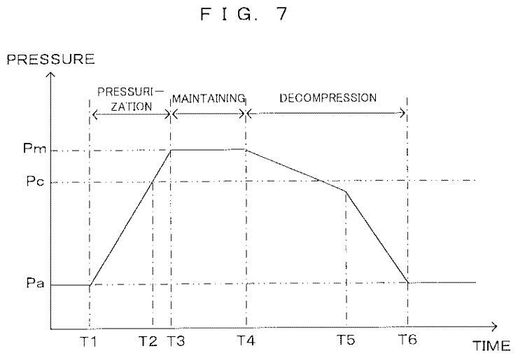

FIG. 7 is a chart showing a pressure change in the processing chamber. If the processing fluid is carbon dioxide, a temperature change during the processing is not very large since a critical temperature of the processing fluid is not very different from a room temperature. Here, a phenomenon is described, focusing on the chamber inner pressure, which notably changes. The introduction of the processing fluid is started and the internal pressure starts to increase at time T1 after the processing space SP is closed from a state where the processing space SP is open to atmospheric air and the internal pressure is an atmospheric pressure Pa.

Pressurization is continued until the pressure of the processing fluid increases in the processing space SP and exceeds a critical pressure Pc in the processing space SP (Step S107). At time T2 at which the critical pressure Pc is reached in the chamber, the processing fluid enters the supercritical state in the chamber. That is, the processing fluid transitions from the gas phase to the supercritical state due to a phase change in the processing space SP. By filling the processing space SP with the processing fluid in the supercritical state, the IPA (or mixed fluid of the IPA and the DIW) covering the substrate is replaced by the processing fluid in the supercritical state. The IPA and the like liberated from the surface of the substrate S is discharged from the processing chamber 412 together with the processing fluid while being dissolved in the processing fluid, and removed from the substrate S. That is, the processing fluid in the supercritical state has a function of replacing the IPA (or mixed fluid of the IPA and the DIW) adhering to the substrate S and serving as a liquid to be replaced, and discharging the liquid to be replaced to the outside of the processing chamber 412.

By continuing a state where the processing space SP is filled with the processing fluid in the supercritical state for a predetermined time after time T3 at which the processing fluid has reliably transitioned into the supercritical state (Steps S108, S109), the liquid to be replaced adhering to the substrate S can be completely replaced and discharged to the outside of the chamber. Note that although a chamber inner pressure Pm in the supercritical state is shown to be constant in FIG. 7, the pressure may fluctuate within such a range as not to fall to or below the critical pressure Pc.

If the replacement of the liquid to be replaced by the processing fluid in the supercritical state is finished in the processing chamber 412 at time T4 (Step S109), the processing fluid in the processing space SP is discharged and the substrate S is dried. Specifically, the inside of the processing chamber 12 filled with the processing fluid in the supercritical state is decompressed by increasing the discharge amount of the fluid from the processing space SP (Step S110).

In a decompression process, the supply of the processing fluid may be stopped or a small amount of the processing fluid may be continuously supplied. By decompression from the state where the processing space SP is filled with the processing fluid in the supercritical state, the phase of the processing fluid changes from the supercritical state to the gas phase. By discharging the vaporized fluid to outside, the substrate S is dried. At this time, a decompression rate is so adjusted that a solid phase and a liquid phase are not created due to a sudden temperature drop. That is, decompression is performed at a relatively low decompression rate until time T5 at which the pressure reliably falls below the critical pressure Pc after decompression is started at time T4. In this way, the processing fluid in the processing space SP is directly vaporized from the supercritical state and discharged to outside.

At and after time T5 at which the processing fluid is completely vaporized, the decompression rate is increased, whereby decompression to the atmospheric pressure Pa is possible in a short time. By doing so, the processing fluid is not liquefied and the formation of a gas/liquid interface on the substrate S having the surface exposed after drying is avoided for an entire period from time T4 at which decompression is started to time T6 at which the pressure in the chamber falls to the atmospheric pressure Pa.

As just described, in the supercritical dry processing of this embodiment, the liquid adhering to the substrate can be efficiently replaced and prevented from remaining on the substrate S by changing the phase of the processing fluid to the gas phase and discharging the processing fluid after the processing space SP is filled with the processing fluid in the supercritical state. Moreover, the substrate can be dried while avoiding problems caused by the formation of the gas/liquid interface such as the contamination of the substrate and pattern collapse due to the adhesion of impurities.

The processed substrate S is delivered to a post-process (Step S111). That is, the support tray 415 is pulled out from the processing chamber 412 by moving the lid member 413 in the (−Y) direction, and the substrate S is transferred to the external conveying device via the transfer unit 43. At this time, the substrate S is in a dry state. Contents of the post-process are arbitrary. In this way, the processing for one substrate S is completed. If there is a substrate to be processed next, return is made to Step S101, a new substrate S is received and the above processing is repeated.

As described above, according to the first embodiment, the remaining liquid removal processing (Step S104) is performed, following the liquid film formation processing (Step S103). Accordingly, even if the DIW remains on the inner bottom surface of the pattern PT, the remaining DIW is diffused into the IPA, which is a main component of the liquid film LF, by the vibration of the substrate S along the vertical direction Z. That is, the remaining DIW is removed from the pattern PT and a remaining liquid-free state is achieved. Therefore, the supercritical dry processing can be performed in high quality without excessively using the processing fluid in the supercritical state. As a result, a yield can be improved while the consumption of the processing fluid is reduced.

Further, in the first embodiment, reciprocal movements of the chuck pins 212 in the radial direction D are utilized to apply vibration to the substrate S. That is, the chuck pins 212 exhibit a vibration application function, besides a function of sandwiching the side edge part of the substrate S and holding the substrate S. Therefore, it is not necessary to add a configuration dedicated to the vibration application function, wherefore device cost can be reduced.

As described above, in the first embodiment, the DIW and the IPA respectively correspond to examples of a “liquid” and an “organic solvent” of the invention. Further, the surface Sa of the substrate S corresponds to an example of a “pattern formed surface” of the invention. Further, the liquid film formation processing (Step S103) corresponds to an example of a “operation (a)” of the invention, the remaining liquid removal processing (Step S104) corresponds to examples of a “operation (d)” and a “first vibration application processing” of the invention, the substrate conveyance processing (Step S105) corresponds to an example of a “operation (b)” of the invention, and the supercritical dry processing (Steps S108 to S110) corresponds to an example of a “operation (c)” of the invention.

Note that although the substrate S is vibrated in the vertical direction Z to perform the remaining liquid removal processing in the first embodiment, a vibration application mode is not limited to this. For example, the wet processing controller 95 may give a forward/reverse rotation command to the rotating mechanism 214 with the substrate S held by the chuck pins 212. In this case, the rotating mechanism 214 having received the forward/reverse rotation command repeats an operation of rotating the substrate S forward and backward by a predetermined angle about the axis of rotation AX, i.e. a pivoting operation. In this way, vibration may be applied to the substrate S by the operation of pivoting the substrate S in a circumferential direction (second embodiment).

Further, vibration may be applied to the substrate S by a separately added configuration without applying vibration along the vertical direction Z by the chuck pins 212 (hereinafter, referred to as “vertical vibration application”) or applying vibration along the circumferential direction by the rotating mechanism 214 (hereinafter, referred to as “pivot vibration application”). For example, following the liquid film formation processing (Step S103), the wet processing controller 95 may actuate an ultrasonic vibrator installed at a position separated from the substrate holder 21 and vibrate the substrate S by ultrasonic waves generated by the ultrasonic vibrator (third embodiment). Further, a vibrator may be mounted in the substrate holder 21 in advance, and the wet processing controller 95 may actuate the vibrator, following the liquid film formation processing (Step S103) (fourth embodiment). In these embodiments, a vibration direction of the substrate S can be controlled by a vibrator installation mode. Note that conventionally known ones can be used as the vibrator and the ultrasonic vibrator. Therefore, the detailed configurations are not described in this specification.

Although vibration is applied to the substrate S in the liquid-filled state in the wet processing device 2 in the above first to fourth embodiments, vibration may be applied in the substrate conveying device 3 or the supercritical processing device 4. A fifth embodiment in which vibration is applied in the substrate conveying device 3 and a sixth embodiment in which vibration is applied in the supercritical processing device 4 are successively described.

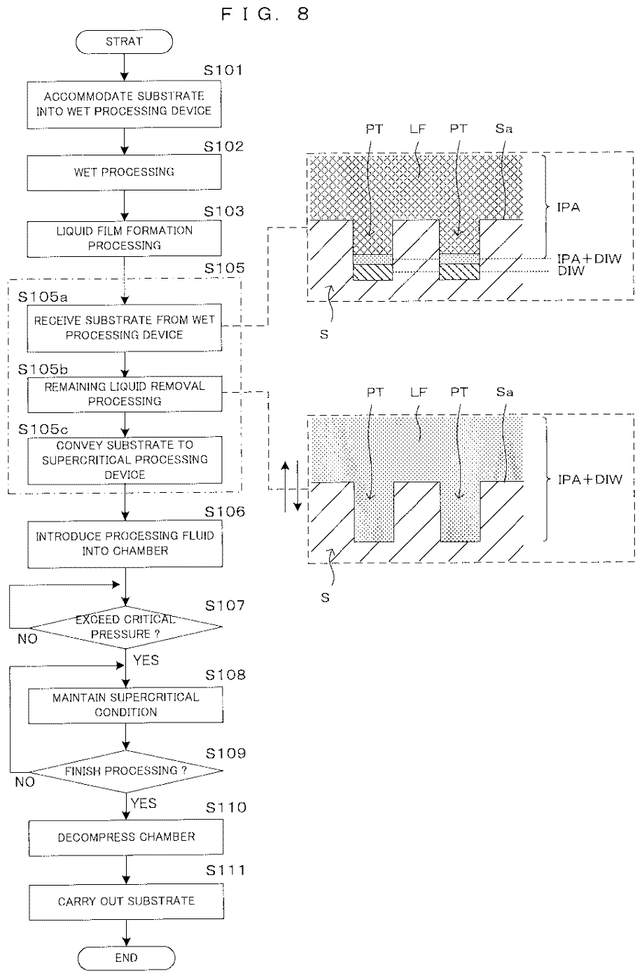

FIG. 8 is a flow chart outlining a processing performed by a substrate processing system according to the fifth embodiment. The fifth embodiment largely differs from the first embodiment in that the remaining liquid removal processing is performed in the substrate conveying device 3. Therefore, the following description is centered on points of difference and the same components are denoted by the same reference signs and are not described.

A substrate S to be processed is accommodated into the wet processing device 2 constituting the substrate processing system 1 (Step S101). In the wet processing device 2, a wet processing (Step S102) and a liquid film formation processing (Step S103) are performed for the substrate S. Then, the remaining liquid removal processing in the wet processing device 2 is deferred and the substrate S in a liquid-filled state filled with IPA serving as an example of an organic solvent is conveyed from the wet processing device 2 to the supercritical processing device 4 by the substrate conveying device 3 (Step S105).

In the fifth embodiment, the remaining liquid removal processing is performed during the above conveyance. The conveyor robot 30 is movable toward and away from both the wet processing device 2 and the supercritical processing device 4 while supporting the substrate S in the liquid-filled state from below. Therefore, the conveyor robot 30 can not only carry the substrate S in and out from each of the wet processing device 2 and the supercritical processing device 4, but also reciprocate and rotate the hand 31 supporting the substrate S in the horizontal direction. Accordingly, in the fifth embodiment, vibration along the horizontal direction can be applied to the substrate S by repeating the reciprocal movements and pivoting of the hand 31. For example, as shown in FIG. 8, a conveying step (Step S105) from the wet processing device 2 to the supercritical processing device 4 includes the following three sub-steps (Steps S105a to S105c). To perform these sub-steps, the operation of the conveyor robot 30 is controlled by the conveyance controller 96 of the control device 9.

In Step S105a, the conveyance controller 96 controls the conveyor robot 30 such that the hand 31 enters the wet processing device 2 and receives the substrate S in the liquid-filled state. At this point of time, DIW may remain on the inner bottom surface of a pattern PT as shown in a right upper figure of FIG. 8. Accordingly, to remove the remaining liquid (DIW), the conveyance controller 96 gives a vibration command to the conveyor robot 30. The conveyor robot 30 having received this command applies vibration to the substrate S by reciprocating the hand 31 by a predetermined distance in a horizontal plane and rotating the hand 31 in forward and reverse directions while holding the substrate S in the liquid-filled state. Then, as in the first embodiment, the remaining liquid is transferred and diffused into the IPA (Step S105b). In this way, even if the DIW remains on the inner bottom surface of the pattern PT when the conveyor robot 30 receives the substrate S, the remaining liquid can be removed as shown in a right lower figure of FIG. 8 (remaining liquid removal processing). After this remaining liquid removal processing is completed, the conveyor robot 30 conveys the substrate in the liquid-filled state to the processing unit 41 of the supercritical processing device 4 as in the first embodiment (Step S105c).

The substrate S conveyed to the supercritical processing device 4 is accommodated into the processing chamber 412 while being kept in the liquid-filled state. Thereafter, the supercritical dry processing is performed in the same procedure as in the first embodiment (Steps S106 to S110). Then, the processed substrate S is delivered to a post-process (Step S111).

As described above, according to the fifth embodiment, the remaining liquid removal processing (Step S105b) is performed in the substrate conveying device 3. Accordingly, even if the DIW remains on the inner bottom surface of the pattern PT, the remaining DIW is diffused into the IPA constituting the liquid film LF by the vibration of the substrate S along the horizontal direction or the vibration of the substrate S caused by rotation in the horizontal plane. That is, the remaining DIW is removed from the pattern PT and the remaining liquid-free state is achieved. Therefore, as in the first embodiment, the supercritical dry processing can be performed in high quality without excessively using the processing fluid in the supercritical state. As a result, a yield can be improved while the consumption of the processing fluid is reduced.

Further, also in the fifth embodiment, it is not necessary to add a configuration dedicated to the vibration application function to the substrate conveying device 3 to vibrate the substrate S utilizing a basic operation of the conveyor robot 30. Therefore, device cost can be reduced.

As described above, in the fifth embodiment, the remaining liquid removal processing (Step S105b) corresponds to examples of the “operation (d) and a “second vibration application processing” of the invention.

Note that although the remaining liquid removal processing is performed when the hand 31 enters the wet processing device 2 and receives the substrate S in the liquid-filled state in the fifth embodiment, an execution timing of the remaining liquid removal processing is not limited to this. For example, the remaining liquid removal processing may be performed while the hand 31 is moving to the supercritical processing device 4 or while the hand 31 is waiting on standby near the supercritical processing device 4.

Further, to wait the conveyance of the substrate S to the supercritical processing device 4 according to an operational status of the supercritical processing device 4, another standby position may be provided, besides the setting of the standby position near the supercritical processing device 4 as described above. For example, if the substrate conveying device 3 includes a mounting table, on which the substrate S in the liquid-filled state is temporarily placed and waits on standby, this mounting table functions as a standby position. Therefore, a vibrator may be mounted in this mounting table and vibration may be applied to the substrate S waiting on standby on the mounting table. That is, the remaining liquid removal processing may be performed at the standby position where the mounting table is provided.

Further, although the hand 31 is vibrated along the horizontal direction or pivoted in the horizontal plane to perform the remaining liquid removal processing in the fifth embodiment, vibration may be given in another mode depending on the configuration of the conveyor robot 30. For example, the conveyor robot 30 may be configured to be able to move the hand 31 in the vertical direction Z. In such a case, the substrate S may be vibrated by lifting and lowering the hand 31 holding the substrate S in the liquid-filled state in the vertical direction Z. Further, as in the third and fourth embodiments, the hand 31 may be vibrated.

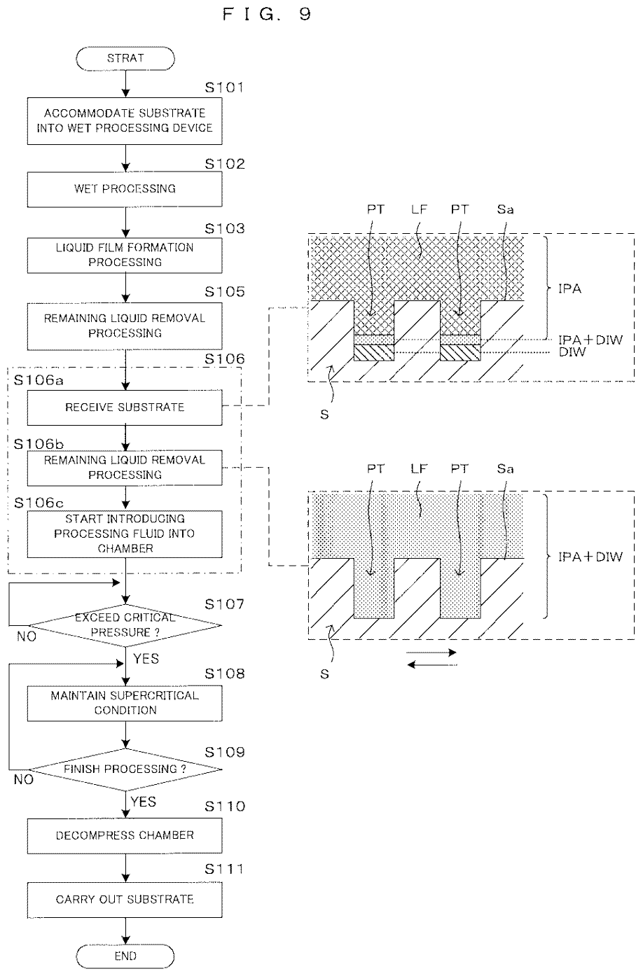

FIG. 9 is a flow chart outlining a processing performed by a substrate processing system according to the sixth embodiment. The sixth embodiment largely differs from the first embodiment in that the remaining liquid removal processing is performed in the supercritical processing device 4. Therefore, the following description is centered on points of difference and the same components are denoted by the same reference signs and are not described.

A substrate S to be processed is accommodated into the wet processing device 2 constituting the substrate processing system 1 (Step S101). In the wet processing device 2, a wet processing (Step S102) and a liquid film formation processing (Step S103) are performed for the substrate S. Then, the remaining liquid removal processing in the wet processing device 2 is deferred and the substrate S in a liquid-filled state filled with IPA serving as an example of an organic solvent is conveyed from the wet processing device 2 to the supercritical processing device 4 by the substrate conveying device 3 (Step S105).

In the sixth embodiment, the substrate S conveyed to the supercritical processing device 4 is accommodated into the processing chamber 412 while being kept in the liquid-filled state. Specifically, the substrate S is conveyed with the pattern formed surface faced up and covered with a thin liquid film LF. As shown by dotted lines in FIG. 4, the lift pins 437 are lifted with the lid member 413 moved to the (−Y) side and the support tray 415 pulled out. The conveying device transfers the substrate S to the lift pins 437. By lowering the lift pins 437, the substrate S is placed on the support tray 415. In this way, the reception of the substrate S is completed (Step S106a).

At this point of time, DIW may remain on the inner bottom surface of a pattern PT as shown in a right upper figure of FIG. 9. Accordingly, to remove the remaining liquid (DIW), the conveyance controller 96 gives a vibration command to the supercritical processing controller 97. The supercritical processing controller 97 having received this command reciprocates the support tray 415 and the lid member 41 along the Y direction while holding the substrate S in the liquid-filled state. By applying vibration to the substrate S by these reciprocal movements, the remaining liquid is transferred and diffused into the IPA (Step S106b) as in the first embodiment. In this way, even if the DIW remains on the inner bottom surface of the pattern PT when the support tray 415 receives the substrate S, the remaining liquid can be removed as shown in a right lower figure of FIG. 9 (remaining liquid removal processing). After this remaining liquid removal processing is completed, the support tray 415 and the lid member 413 integrally move in the (+Y) direction as in the first embodiment, whereby the support tray 415 supporting the substrate S is accommodated into the processing space SP in the processing chamber 412 and the opening 421 is closed by the lid member 413. In this state, carbon dioxide serving as a processing fluid is introduced in a gas phase state into the processing space SP (Step S106c). Outside air enters the processing space SP when the substrate S is carried in, but this can be replaced by introducing the processing fluid in a gas phase. Further, by injecting the processing fluid in the gas phase, a pressure in the processing chamber 412 increases.

Pressurization is continued until the pressure of the processing fluid increases in the processing space SP and exceeds the critical pressure Pc (Step S107). Thereafter, as in the first embodiment, the supercritical dry processing is performed (Steps S108 to S110). Then, the processed substrate S is delivered to a post-process (Step S111).

As described above, according to the sixth embodiment, the remaining liquid removal processing (Step S106b) is performed in the supercritical processing device 4 before the processing fluid in the supercritical state is brought into contact with the substrate S. Accordingly, even if the DIW remains on the inner bottom surface of the pattern PT, the remaining DIW is diffused into the IPA constituting the liquid film LF by the vibration of the substrate S along the Y direction. That is, the remaining DIW is removed from the pattern PT and a remaining liquid-free state is achieved. Therefore, as in the first embodiment, the supercritical dry processing can be performed in high quality without excessively using the processing fluid in the supercritical state. As a result, a yield can be improved while the consumption of the processing fluid is reduced.

Further, also in the sixth embodiment, it is not necessary to add a configuration dedicated to the vibration application function to the supercritical processing device 4 to vibrate the substrate S utilizing basic operations of the support tray 415 and the lid member 413. Therefore, device cost can be reduced.

As described above, in the sixth embodiment, the remaining liquid removal processing (Step S106b) corresponds to examples of the “operation (d)” and a “third vibration application processing” of the invention.

Although the support tray 415 and the lid member 413 are vibrated along the Y direction to perform the remaining liquid removal processing in the sixth embodiment, a vibrator may be mounted in the support tray 415 or the lid member 413. That is, the substrate S may be vibrated by actuating the vibrator in response to a vibration command from the supercritical processing controller 97.

Further, although the remaining liquid removal processing is performed before the pressure in the processing chambers 412 increases in the sixth embodiment, the remaining liquid removal processing may be performed during a pressure increase before critical conditions are reached. For example, the remaining liquid removal processing may be performed in a subcritical state. Particularly, if an elapsed time from the execution of the remaining liquid removal processing to the start of contact with the processing fluid in the supercritical state is considered, the remaining liquid removal processing is preferably performed at a timing close to the subcritical state. That is, there is a possibility that, as the elapsed time becomes longer, such as due to a specific gravity of the DIW larger than that of the IPA, part of the DIW diffused into the IPA precipitates to the inner bottom surface of the pattern PT to increase a DIW concentration. The execution timing of the remaining liquid removal processing is preferably set in view of this point.

Note that the invention is not limited to the embodiments described above and various changes other than the aforementioned ones can be made without departing from the gist of the invention. Although the remaining liquid removal processing is performed only once in applying the wet processing and the supercritical dry processing to one substrate S, the remaining liquid removal processing may be performed a plurality of times. That is, at least one of the first to third vibration application processings may be performed.

Further, various chemical substances used in the processings of the above embodiments are some examples, and various others can be used if these are consistent with the technical concept of the invention described above.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

This invention can be applied to techniques in general for drying a substrate by a processing fluid in a supercritical state in a chamber.

What is claimed is:

1. A substrate processing method for drying a substrate having a pattern formed surface formed with a pattern and a liquid adhering to the pattern formed surface, the method comprising:
(a) creating a liquid-filled state in which an organic solvent is filled on the pattern formed, the organic solvent being supplied to the pattern formed surface to replace the liquid in a wet processing device;
(b) conveying the substrate in the liquid-filled state from the wet processing device to a supercritical processing device;
(c) drying the substrate by bringing a processing fluid in a supercritical state into contact with the pattern formed surface in the liquid-filled state in the supercritical processing device; and
(d) mixing the liquid remaining in the pattern with the organic solvent by applying vibration to the substrate while maintaining the liquid-filled state before the processing fluid in the supercritical state is brought into contact with the pattern formed surface.

2. The substrate processing method according to claim 1, wherein:
the operation (d) is performed after the operation (a) is performed in the wet processing device.

3. The substrate processing method according to claim 2, wherein:
the operation (a) is performed with the substrate sandwiched and held by a plurality of chuck pins in a horizontal direction while a peripheral edge part of the substrate is supported from below by the plurality of chuck pins,
the operation (b) is performed under a releasing state in which the sandwiching of the substrate by the plurality of chuck pins is released while the peripheral edge part of the substrate is supported from below by the plurality of chuck pins, and
in the operation (d), the vibration is applied to the substrate by reciprocating the plurality of chuck pins between a sandwiching position for sandwiching the substrate and a releasing position separated from the sandwiching position.

4. The substrate processing method according to claim 2, wherein:
in the operation (a), the organic solvent is supplied to the pattern formed surface while the substrate is rotated about a predetermined axis of rotation, and
in the operation (d), the vibration is applied to the substrate by pivoting the substrate about the axis of rotation.

5. The substrate processing method according to claim 2, wherein:
in the operation (a), the organic solvent is supplied to the substrate while the substrate is held by a substrate holder, and
in the operation (d), the vibration is applied to the substrate by actuating a vibrator mounted in the substrate holder.

6. The substrate processing method according to claim 2, wherein:
in the operation (a), the organic solvent is supplied to the substrate while the substrate is held by a substrate holder, and
in the operation (d), the vibration is applied to the substrate by actuating an ultrasonic vibrator arranged away from the substrate holder and the substrate.

7. The substrate processing method according to claim 1, wherein:
the operation (d) is performed during execution of the operation (b).

8. The substrate processing method according to claim 7, wherein:
the operation (b) includes:
(b-1) receiving the substrate from the wet processing device by a hand of a conveyor robot;
(b-2) moving the hand having received the substrate to the supercritical processing device; and
(b-3) transferring the substrate from the hand to the supercritical processing device, and
the operation (d) is performed immediately after execution of the operation (b-1) or during execution of the operation (b-2).

9. The substrate processing method according to claim 7, wherein:
the operation (b) includes:
(b-1) receiving the substrate from the wet processing device by a hand of a conveyor robot;
(b-2-1) moving the hand having received the substrate to a standby position near the supercritical processing device;
(b-2-2) causing the hand to wait on standby at the standby position,
(b-2-3) moving the hand from the standby position to the supercritical processing device; and
(b-3) transferring the substrate from the hand to the supercritical processing device, and
the operation (d) is performed during execution of any one of the operations (b-2-1) to (b-2-3).

10. The substrate processing method according to claim 8, wherein:
in the operation (d), the vibration is applied to the substrate by reciprocating the hand or rotating the hand.

11. The substrate processing method according to claim 8, wherein:
in the operation (d), the vibration is applied to the substrate by actuating a vibrator mounted in the hand.

12. The substrate processing method according to claim 9, wherein:
in the operation (d), the vibration is applied to the substrate by reciprocating the hand or rotating the hand.

13. The substrate processing method according to claim 9, wherein:
in the operation (d), the vibration is applied to the substrate by actuating a vibrator mounted in the hand.

14. The substrate processing method according to claim 1, wherein:
the operation (d) is performed before the processing fluid in the supercritical state is brought into contact with the pattern formed surface in the liquid-filled state in the supercritical processing device.

15. The substrate processing method according to claim 14, wherein:
the operation (c) includes:
(c-1) placing the substrate on a support tray;
(c-2) accommodating the substrate into a supercritical processing chamber by moving the support tray in a horizontal direction with the substrate placed on the support tray;
(c-3) increasing a pressure in the processing chamber accommodating the substrate; and
(c-4) super-critically drying the substrate by bringing the processing fluid in the supercritical state into contact with the substrate in the processing chamber, and
in the operation (d), the vibration is applied to the substrate by reciprocating the support tray in the horizontal direction before execution of the operation (c-4).

16. The substrate processing method according to claim 14 wherein:
the operation (c) includes:
(c-1) lacing the substrate on a support tray;
(c-2) accommodating the substrate into a supercritical processing chamber by moving the support tray in a horizontal direction with the substrate placed on the support tray;
(c-3) increasing a pressure in the processing chamber accommodating the substrate; and
(c-4) super-critically drying the substrate by bringing the processing fluid in the supercritical state into contact with the substrate in the processing chamber, and
in the operation (d), the vibration is applied to the substrate by actuating a vibrator mounted in the support tray before execution of the operation (c-4).

17. A substrate processing system for drying a substrate having a pattern formed surface formed with a pattern and a liquid adhering to the pattern formed surface, the system comprising:
a wet processing device configured to create a liquid-filled state in which an organic solvent is filled on the pattern formed, the organic solvent being supplied to the pattern formed surface to replace the liquid;
a supercritical processing device configured to dry the substrate by bringing a processing fluid in a supercritical state into contact with the pattern formed surface in the liquid-filled state;
a substrate conveying device configured to convey the substrate in the liquid-filled state from the wet processing device to the supercritical processing device; and
a control device configured to control the wet processing device, the substrate conveying device and the supercritical processing device to perform at least one of a first vibration application processing to a third vibration application processing, the first vibration application processing being a process of applying vibration to the substrate after the liquid-filled state is created in the wet processing device, the second vibration application processing being a process of applying vibration to the substrate in the substrate conveying device, the third vibration application processing being a process of applying vibration to the substrate before the processing fluid in the supercritical state is brought into contact with the pattern formed surface in the supercritical processing device.
